(19) United States
(12) Patent Application Publication
(10) Pub. No.: US 2021/0214836 A1
(43) Pub. Date: Jul. 15, 2021

(54) MASK DEVICE AND EVAPORATION METHOD

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Fengli JI, Beijing (CN); Shaoduan LIANG, Beijing (CN); Xiaoyu YANG, Beijing (CN); Fangfang DUAN, Beijing (CN); Chang LUO, Beijing (CN)

(21) Appl. No.: 17/059,913

(22) PCT Filed: Apr. 24, 2020
(86) PCT No.: PCT/CN2020/086685

§ 371 Date: Nov. 30, 2020

(30) Foreign Application Priority Data
Apr. 30, 2019 (CN) 201910365172.1

(51) Int. Cl. C23C 14/04; C23C 14/24

(52) U.S. Cl. CPC C23C 14/042; C23C 14/24

(57) ABSTRACT

The present disclosure provides a mask device and an evaporation method. The mask device includes a first mask plate. The first mask plate includes a first frame, and a first mask strip on the first frame. The first mask strip includes: a first sub-mask strip and a second sub-mask strip spliced with each other; the first sub-mask strip includes a first hollow region; and a thickness of a central region of the second sub-mask strip is less than a thickness of an edge region of the second sub-mask strip, the edge region of the second sub-mask strip surrounding the central region of the second sub-mask strip.

### CROSS REFERENCE TO RELATED APPLICATIONS

This is a National Phase Application filed under 35 U.S.C. 371 as a national stage of PCT/CN2020/086685, filed on Apr. 24, 2020, an application claiming priority to Chinese patent application No. 201910365172.1, filed on Apr. 30, 2019 in State Intellectual Property Office of P.R.C, the entire contents of which are incorporated herein by reference.

### TECHNICAL FIELD

The present disclosure belongs to the field of display technologies, and in particular, to a mask device and an evaporation method.

### BACKGROUND

An Organic Light Emitting Diode (OLED) display device has advantages of being light, thin, low in power consumption, high in contrast, high in color gamut, capable of achieving flexible display, and the like, and is a development trend of next-generation display. The OLED display device includes an active matrix organic light emitting diode (AMOLED) display device.

In the production process of the AMOLED display panel, a metal mask plate is generally used in evaporation of the light emitting material. With the increasing demand of the market on large-size and on-vehicle display screens, the realization of high-precision metal mask plates for evaporation of large-size products is urgent.

### SUMMARY

One aspect of the present disclosure provides a mask device, including a first mask plate, and the first mask plate includes a first frame and a first mask strip on the first frame. The first mask strip includes: a first sub-mask strip and a second sub-mask strip spliced with each other; the first sub-mask strip includes a first hollow region; and a thickness of a central region of the second sub-mask strip is less than a thickness of an edge region of the second sub-mask strip, the edge region of the second sub-mask strip surrounding the central region of the second sub-mask strip.

In some embodiments, the thickness of the central region of the second sub-mask strip is 0.4 to 0.6 times the thickness of the edge region of the second sub-mask strip.

In some embodiments, the thickness of the edge region of the second sub-mask strip is less than a thickness of the first sub-mask strip.

In some embodiments, the first mask plate includes a first shielding strip arranged side by side with the first mask strip, and the first shielding strip is provided with an alignment mark.

In some embodiments, the alignment mark includes an alignment hole.

In some embodiments, the first mask plate includes a plurality of first mask strips and a plurality of first shielding strips arranged side by side, and the plurality of first mask strips and the plurality of first shielding strips are alternately arranged.

In some embodiments, the mask device further includes a second mask plate. The second mask plate includes: a second frame and a second mask strip on the second frame. The second mask strip includes a third sub-mask strip and a fourth sub-mask strip spliced with each other; the fourth sub-mask strip includes a second hollow region; and a thickness of a central region of the third sub-mask strips is less than a thickness of an edge region of the third sub-mask strip, the edge region of the third sub-mask strip surrounding the central region of the third sub-mask strip. In a case where orientations of the first mask plate and the second mask plate are the same, a relative position relation of the spliced first and second sub-mask strips is the same as a relative position relation of the spliced third and fourth sub-mask strips.

In some embodiments, the thickness of the central region of the third sub-mask strip is 0.4 to 0.6 times the thickness of the edge region of the third sub-mask strip.

In some embodiments, the thickness of the edge region of the third sub-mask strip is less than a thickness of the fourth sub-mask strip.

In some embodiments, the second mask plate includes a second shielding strip arranged side by side with the second mask strip, and the second shielding strip is provided with an alignment mark.

In some embodiments, the alignment mark includes an alignment hole.

In some embodiments, the second mask plate includes a plurality of second mask strips and a plurality of second shielding strips arranged side by side, and the plurality of second mask strips and the plurality of second shielding strips are alternately arranged.

The present disclosure also provides an evaporation method using a mask device, and the mask device is the mask device according to the present disclosure. The method includes: aligning an evaporation object with the first mask plate such that the first hollow region of the first mask plate aligns with a first portion of a to-be-evaporated region on the evaporation object; performing evaporation on the first portion of the to-be-evaporated region by using the first mask plate; and performing evaporation on a second portion of the to-be-evaporated region except the first portion.

In some embodiments, the first portion and the second portion have a same size. Performing evaporation on the second portion of the to-be-evaporated region includes: moving the evaporation object; aligning the evaporation object with the first mask plate such that the first hollow region aligns with the second portion of the to-be-evaporated region; and performing evaporation on the second portion of the to-be-evaporated region by using the first mask plate.

In some embodiments, the mask device further includes a second mask plate. The second mask plate includes: a second frame and a second mask strip on the second frame. The second mask strip includes a third sub-mask strip and a fourth sub-mask strip spliced with each other; the fourth sub-mask strip includes a second hollow region; and a thickness of a central region of the third sub-mask strip is less than a thickness of an edge region of the third sub-mask strip, the edge region of the third sub-mask strip surrounding the central region of the third sub-mask strip. In a case where orientations of the first mask plate and the second mask plate are the same, a relative position relation of the spliced first and second sub-mask strips is the same as a relative position relation of the spliced third and fourth sub-mask strips. Performing evaporation on the second portion of the to-be-evaporated region includes: moving the evaporation object; aligning the evaporation object with the second mask plate such that the second hollow region of the second mask plate aligns with the second portion of the to-be-evaporated region; and performing evaporation on a remaining portion of the to-be-evaporated region by using the second mask plate.

In some embodiments, the first mask plate includes a first shielding strip arranged side by side with the first mask strip, and the first shielding strip is provided with an alignment mark. Aligning the evaporation object with the first mask plate includes aligning the evaporation object with the first mask plate by using the alignment mark on the first shielding strip.

In some embodiments, the second mask plate includes a second shielding strip arranged side by side with the second mask strip, and the second shielding strip is provided with an alignment mark. Aligning the evaporation object with the second mask plate includes aligning the evaporation object with the second mask plate by using the alignment mark on the second shielding strip.

### BRIEF DESCRIPTION OF THE DRAWINGS

In order to more clearly illustrate the technical solutions of the embodiments of the present disclosure, the drawings used in the description of the embodiments of the present disclosure will be briefly introduced below, and it is obvious that the drawings in the description below are only some embodiments of the present disclosure, and for those skilled in the art, other drawings may be obtained according to the drawings without inventive labor.

FIG. 1 is a schematic structural diagram of a mask device in a related art according to an embodiment of the present disclosure;

FIG. 2 is a schematic structural diagram of a mask device according to an embodiment of the disclosure;

FIG. 3 is a schematic structural diagram of another mask device according to an embodiment of the present disclosure;

FIG. 4 is a schematic flow chart of an evaporation method according to an embodiment of the present disclosure;

FIG. 5 is a schematic flow chart of performing evaporation on a second portion of a to-be-evaporated region according to an embodiment of the present disclosure; and

FIG. 6 is a schematic flow chart of performing evaporation on a second portion of a to-be-evaporated region according to another embodiment of the present disclosure.

### DETAILED DESCRIPTION

The technical solutions in the embodiments of the present disclosure will be described clearly and completely with reference to the accompanying drawings in the embodiments of the present disclosure, and it is apparent that the described embodiments are only some embodiments, but not all embodiments, of the present disclosure. All other embodiments, which can be derived by a person skilled in the art from the embodiments disclosed herein without inventive step, are intended to be within the scope of the present disclosure.

The existing evaporation method using a large-size mask plate has the following problems: manufacturers cannot manufacture a corresponding large-width mask plate; the large-size mask plate results in that the drooping amount of the central region of the mask plate is increased, the wrinkles are intensified, and the yield in the screen spreading is reduced; the size of the mask plate is increased, and the clamp of the screen spreading equipment cannot correspond to the mask plate, so that the screen spreading cannot be finished by the conventional equipment.

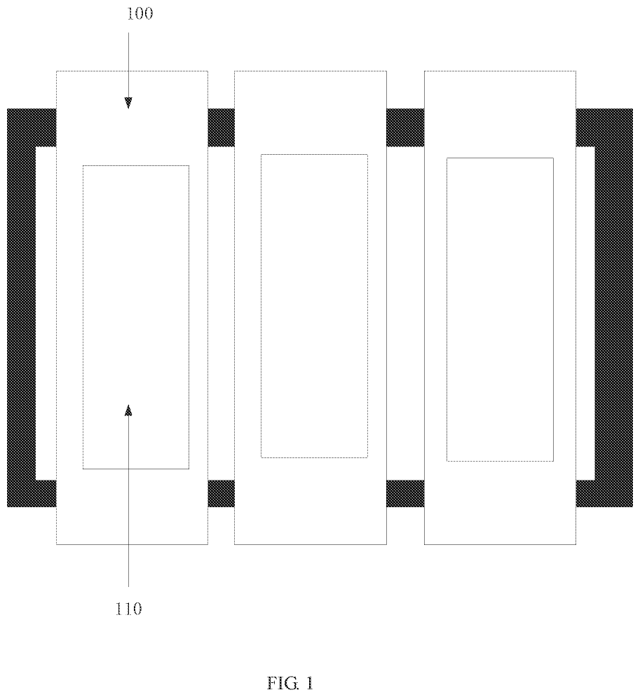

Typically, mask strips are arranged side by side on the frame. FIG. 1 illustrates a mask device in the related art, which includes mask strips 100 each provided with a hollow region 110. As the size of the display screen becomes larger, the size of the mask plate also becomes larger. In this case, the mask strip 100 becomes wider, and the hollow region 110 also becomes larger. However, it is not possible to make a relatively wide mask strip 100, and the wide mask strip may result in a low precision in screen spreading or may not correspond to the screen spreading equipment.

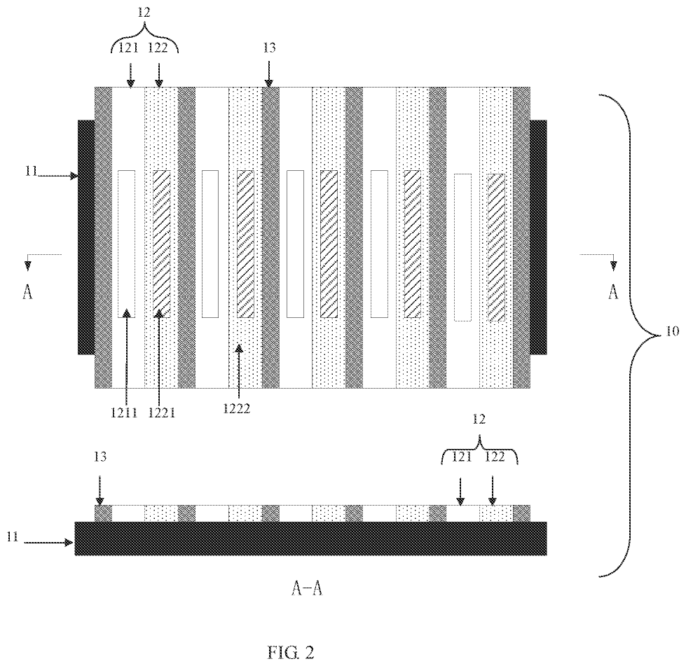

Referring to FIG. 2, the present disclosure provides a mask device including a first mask plate 10. The first mask plate includes a first frame 11, and first mask strips 12 and first shielding strips 13 which are arranged on the first frame 11 side by side, and the first mask strip 12 and the first shielding strip 13 are alternately arranged. The adjacent first mask strip 12 and first mask strip 13 are closely attached.

The first mask strip 12 includes: a first sub-mask strip 121 and a second sub-mask strip 122 spliced with each other. The first sub-mask strip 121 is provided with a first hollow region 1211.

The second sub-mask strip 122 has a central region 1221 and an edge region 1222 surrounding the central region 1221. The central region 1221 of the second sub-mask strip 122 has a thickness smaller than that of the edge region 1222.

In an embodiment of the present disclosure, the thickness of the central region 1221 of the second sub-mask strip 122 is 0.4 to 0.6 times the thickness of the edge region.

In an embodiment of the present disclosure, the central region of the second sub-mask strip 122 is configured to be thinner, so that the central region of the mask strip can be prevented from drooping due to the too large width of the mask strip.

In an embodiment of the present disclosure, the thickness of the edge region of the second sub-mask strip 122 is smaller than that of the first sub-mask strip 121.

In an embodiment of the present disclosure, the second sub-mask strip 122 is thinner, which can reduce the overall weight of the second mask strip, and prevent the central region of the second mask strip from drooping, thereby preventing the influence on the subsequent evaporation using the first mask plate.

In an embodiment of the present disclosure, the first shielding strip 13 is provided with an alignment mark. For example, the alignment mark may be an alignment hole. The alignment hole may be formed in the first shielding strip using laser cutting. In addition, the alignment hole may be formed in the first shielding strip after screen spreading is performed on the first mask plate, which can effectively promote the alignment accuracy.

In the present disclosure, the alignment mark is used to facilitate alignment between the first mask plate and an object to be evaporated, when evaporation is performed on the object to be evaporated.

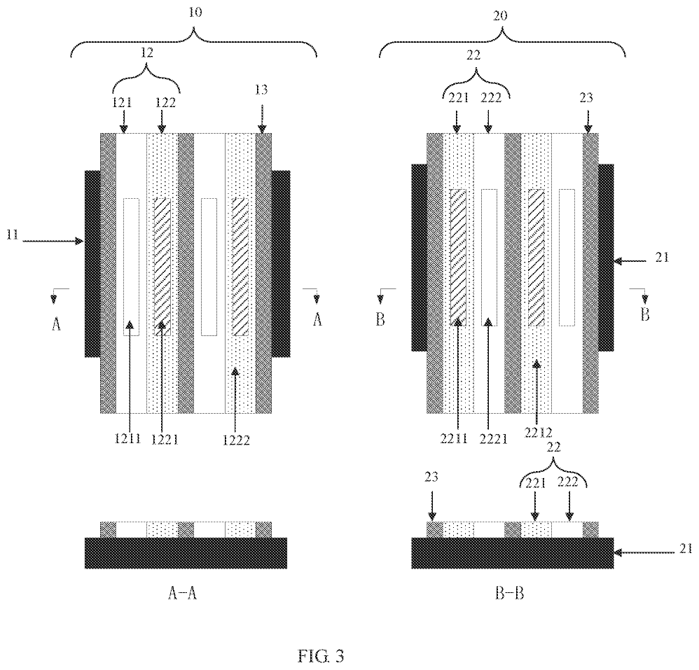

In an embodiment of the present disclosure, referring to FIG. 3, the mask device further includes: a second mask plate 20.

The second mask plate 20 includes a second frame 21, and second mask strips 22 and second shielding strips 23 arranged side by side on the second frame 21. The second mask strip 22 and the second shielding strip 23 are alternately arranged.

The second mask strip 22 includes: a third sub-mask strip 221 and a fourth sub-mask strip 222 spliced with each other; and the fourth sub-mask strip 222 is provided with a second hollow region 2221.

In a case where orientations of the first mask plate 10 and the second mask plate 20 are the same, as shown in FIG. 3, a relative position relation of the spliced first and second sub-mask strips 121 and 122 (in FIG. 3, the first sub-mask strip 121 is on the left side of the second sub-mask strip 122) is the same as a relative position relation of the spliced third and fourth sub-mask strips 221 and 222 (in FIG. 3, the third sub-mask strip 221 is on the left side of the fourth sub-mask strip 222).

In an embodiment of the present disclosure, the third sub-mask strip 221 includes a central region 2211 and an edge region 2212 surrounding the central region 2211, and a thickness of the central region 2211 is smaller than that of the edge region 2212.

In an embodiment of the present disclosure, the thickness of the central region 2211 of the third sub-mask strip 221 is 0.4 to 0.6 times the thickness of the edge region 2212.

In an embodiment of the present disclosure, the first frame 11 and the second frame 21 are identical, the first shielding strip 13 and the second shielding strip 23 are identical, and the first mask strip 12 and the second mask strip 22 are complementary.

In the present disclosure, the second mask strip of the second mask plate and the first mask strip of the first mask plate are complementary, and other portions may be completely identical.

In an embodiment of the present disclosure, the second shielding strip 23 is also provided with an alignment mark. For example, the alignment mark may be an alignment hole. The alignment hole may be formed in the second shielding strip using laser cutting. In addition, the alignment hole may be formed in the second shielding strip after screen spreading is performed on the second mask plate, which can effectively promote the alignment accuracy.

In an embodiment of the present disclosure, the first hollow region 1211 of the first mask plate 10 and the second hollow region 2221 of the second mask plate 20 form a complete hollow region to be evaporated, thereby facilitating evaporation on a complete object to be evaporated.

In an embodiment of the disclosure, the mask strip is split into the two sub-mask strips, so that the width of the mask strip can be effectively reduced, the fabrication difficulty of the mask plate and the screen spreading difficulty of the mask strip are reduced, the precision of each sub-mask strip is improved, the drooping amount of the central region of the mask strip is reduced, and the evaporation precision using the mask plate is improved.

The mask device according to the embodiments of the present disclosure includes: a first mask plate; the first mask plate includes a first frame, and a first mask strip and a first shielding strip on the first frame side by side; and the first mask strip and the first shielding strip are alternately arranged. The first mask strip includes a first sub-mask strip and a second sub-mask strip spliced with each other; a first hollow region is on the first sub-mask strip; and a thickness of a central region of the second sub-mask strip is smaller than a thickness of an edge region of the second sub-mask strip surrounding the central region. According to the embodiments of the disclosure, the mask strip is split into the two sub-mask strips, so that the screen spreading difficulty is reduced, and the fabrication of the large-width mask plate is realized. When the size of the mask plate is increased, the phenomenon that the drooping amount of the central region of the mask strip is increased due to the fact that the mask strip is too wide can be avoided, and the evaporation precision using the large-width mask plate can be improved.

Referring to FIG. 4, an embodiment of the present disclosure provides an evaporation method including steps 201 to 203.

In step 201, an evaporation object is aligned with the first mask plate such that the first hollow region of the first mask plate aligns with a first portion of a to-be-evaporated region on the evaporation object.

In an embodiment of the disclosure, the first mask plate is aligned with the evaporation object by using the alignment mark on the first shielding strip.

In an embodiment of the disclosure, the evaporation object includes a display panel, and the to-be-evaporated region is a region where a pixel defining layer on a glass substrate in the display panel is located.

In an embodiment of the disclosure, the first mask plate is placed on the evaporation object, with the first hollow region aligning with a portion of the to-be-evaporated region, and the second sub-mask strip shielding a remaining portion of the to-be-evaporated region.

In an embodiment of the present disclosure, the evaporation object and the first mask plate may be placed in a vacuum chamber for evaporation.

In step 202, the first portion of the to-be-evaporated region is evaporated by using the first mask plate.

When the evaporation object has a region which does not need to be evaporated thereon, other auxiliary shielding patterns which do not belong to the first mask plate may be used for shielding, in addition to using the second sub-mask strip and first shielding strip of the first mask plate for shielding.

For example, when the to-be-evaporated region is a unit on the screen, half of the region of the unit may be evaporated thereon first.

In step 203, the remaining portion of the to-be-evaporated region is evaporated.

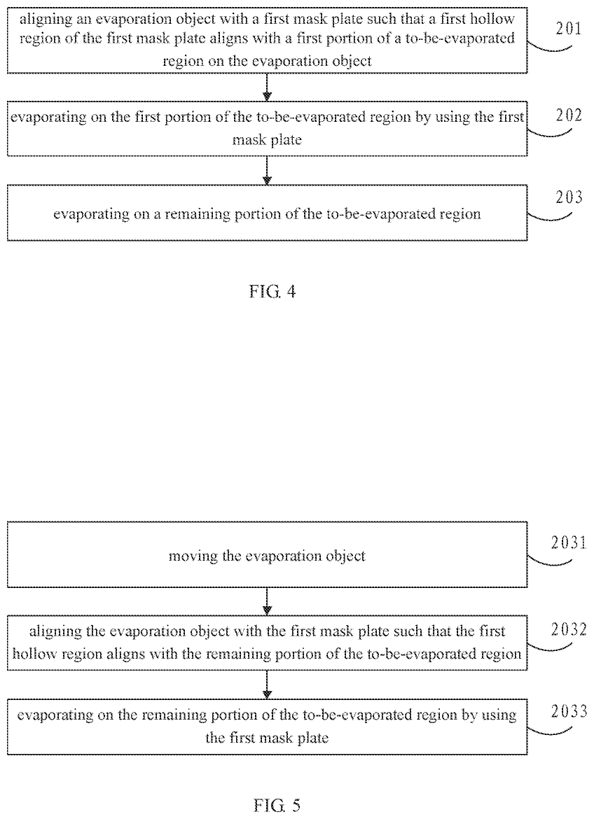

Referring to FIG. 5, the first portion has the same size as the remaining portion, and step 203 may further include steps 2031 to 2033.

In step 2031, the evaporation object is moved.

In step 2032, the evaporation object is aligned with the first mask plate such that the first hollow region aligns with the remaining portion of the to-be-evaporated region.

In step 2033, the remaining portion of the to-be-evaporated region is evaporated by using the first mask plate.

In an embodiment of the present disclosure, in the evaporation on the remaining portion and the first portion of the to-be-evaporated region, the same first mask plate may be used for shielding, and at this time, the first hollow region is aligned with the remaining portion of the to-be-evaporated region. In addition, the evaporation on the first portion and the remaining portion of the to-be-evaporated region may be completed in the same chamber, the evaporation object may be always in the same evaporation environment, and thus only one mask plate is needed, the consistency of the evaporation on the first portion and the remaining portion is high, and the cost is low.

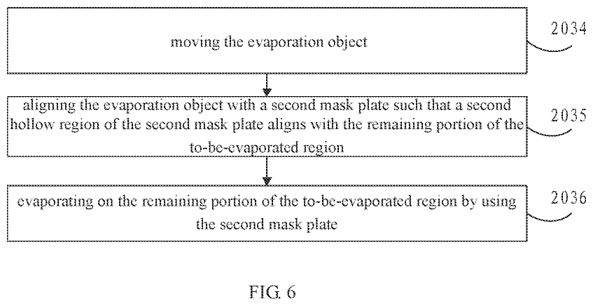

Referring to FIG. 6, the mask device includes a second mask plate, and the second mask plate includes a second frame and a second mask strip disposed on the second frame. The second mask strip includes a third sub-mask strip and a fourth sub-mask strip spliced with each other; the fourth sub-mask strip includes a second hollow region; and a thickness of a central region of the third sub-mask strip is less than that of an edge region of the third sub-mask strip, and the edge region of the third sub-mask strip surrounds the central region of the third sub-mask strip. In the case where the orientations of the first mask plate and the second mask plate are the same, a relative position relation of the spliced first and second sub-mask strips is the same as a relative position relation of the spliced third and fourth sub-mask strips. Step 203 may include steps 2034 to 2036.

In step 2034, the evaporation object is moved.

In step 2035, the evaporation object is aligned with the second mask plate such that the second hollow region of the second mask plate aligns with the remaining portion of the to-be-evaporated region.

In step 2036, the remaining portion of the to-be-evaporated region is evaporated by using the second mask plate.

In an embodiment of the present disclosure, in the evaporation on the remaining portion of the to-be-evaporated region, the second mask plate may be used to perform alignment for evaporation.

In some embodiments, the second mask plate may be placed in the same vacuum chamber as the first mask plate, and the evaporation object is moved to a position corresponding to the second mask plate to perform evaporation on the remaining portion. In some embodiments, the second mask plate may be placed in a different vacuum chamber from the first mask plate. In this case, the step 2034 includes moving the evaporation object from a first chamber to a second chamber. The first mask plate is located in the first chamber, and the second mask plate is located in the second chamber.

In an embodiment of the disclosure, the alignment mark may be directly arranged on the shielding strip, and thus the purchased alignment mask for the alignment can be omitted.

In the evaporation method according to the embodiments of the present disclosure provides, the mask device according to the embodiments of the present disclosure is used. The method includes: aligning an evaporation object with the first mask plate such that the first hollow region of the first mask plate aligns with a first portion of a to-be-evaporated region on the evaporation object; performing evaporation on the first portion of the to-be-evaporated region by using the first mask plate; and performing evaporation on a remaining portion of the to-be-evaporated region. According to the embodiments of the disclosure, the mask strip is spliced into the two sub-mask strips, so that when a large-size display screen is subjected to evaporation, evaporation can be performed through the large-width mask plate, and the evaporation precision of the large-size display screen is improved.

It can be clearly understood by those skilled in the art that, for convenience and simplicity of description, the specific operation processes of the above-described systems, devices and units may refer to the corresponding processes in the foregoing method embodiments, and are not described herein.

The above description is meant to be illustrative of the preferred embodiments of the present disclosure and not to be construed as limiting the disclosure, and any modifications, equivalents, improvements, etc. that fall within the spirit and principle of the present disclosure are intended to be included in the protection scope of the present disclosure.

The above description is only for the specific embodiments of the present disclosure, but the scope of the present disclosure is not limited thereto. Changes or substitutions that can be easily conceived by any person skilled in the art within the technical scope of the present disclosure shall fall within the scope of the present disclosure. Therefore, the protection scope of the present disclosure shall be subject to the protection scope of the claims.

1. A mask device comprising a first mask plate,
the first mask plate comprising:
a first frame; and
a first mask strip on the first frame,
wherein the first mask strip comprises: a first sub-mask strip and a second sub-mask strip spliced with each other; the first sub-mask strip comprises a first hollow region; and a thickness of a central region of the second sub-mask strip is less than a thickness of an edge region of the second sub-mask strip, the edge region of the second sub-mask strip surrounding the central region of the second sub-mask strip.

2. The mask device of claim 1, wherein the thickness of the central region of the second sub-mask strip is 0.4 to 0.6 times the thickness of the edge region of the second sub-mask strip.

3. The mask device of claim 1, wherein the thickness of the edge region of the second sub-mask strip is less than a thickness of the first sub-mask strip.

4. The mask device of claim 1, wherein the first mask plate comprises a first shielding strip arranged side by side with the first mask strip, and the first shielding strip is provided with an alignment mark.

5. The mask device of claim 4, wherein the alignment mark comprises an alignment hole.

6. The mask device of claim 4, wherein the first mask plate comprises a plurality of first mask strips and a plurality of first shielding strips arranged side by side, and the plurality of first mask strips and the plurality of first shielding strips are alternately arranged.

7. The mask device of claim 1, further comprising a second mask plate,
the second mask plate comprising:
a second frame; and
a second mask strip on the second frame,
wherein the second mask strip comprises a third sub-mask strip and a fourth sub-mask strip spliced with each other; the fourth sub-mask strip comprises a second hollow region; and a thickness of a central region of the third sub-mask strip is less than a thickness of an edge region of the third sub-mask strip, the edge region of the third sub-mask strip surrounding the central region of the third sub-mask strip; and
in a case where orientations of the first mask plate and the second mask plate are the same, a relative position relation of the spliced first and second sub-mask strips is the same as a relative position relation of the spliced third and fourth sub-mask strips.

8. The mask device of claim 7, wherein the thickness of the central region of the third sub-mask strip is 0.4 to 0.6 times the thickness of the edge region of the third sub-mask strip.

9. The mask device of claim 8, wherein the thickness of the edge region of the third sub-mask strip is less than a thickness of the fourth sub-mask strip.

10. The mask device of claim 7, wherein the second mask plate comprises a second shielding strip arranged side by side with the second mask strip, and the second shielding strip is provided with an alignment mark.

11. The mask device of claim 10, wherein the alignment mark comprises an alignment hole.

12. The mask device of claim 10, wherein the second mask plate comprises a plurality of second mask strips and a plurality of second shielding strips arranged side by side, and the plurality of second mask strips and the plurality of second shielding strips are alternately arranged.

13. An evaporation method using a mask device, the mask device being the mask device of claim 1, and the method comprising:
aligning an evaporation object with the first mask plate such that the first hollow region of the first mask plate aligns with a first portion of a to-be-evaporated region on the evaporation object;
performing evaporation on the first portion of the to-be-evaporated region by using the first mask plate; and
performing evaporation on a second portion of the to-be-evaporated region other than the first portion.

14. The method of claim 13, wherein the first portion and the second portion have a same size, and performing evaporation on the second portion of the to-be-evaporated region comprises:
moving the evaporation object;
aligning the evaporation object with the first mask plate such that the first hollow region aligns with the second portion of the to-be-evaporated region; and
performing evaporation on the second portion of the to-be-evaporated region by using the first mask plate.

15. The method of claim 13, wherein the mask device further comprises a second mask plate, and the second mask plate comprises a second frame and a second mask strip on the second frame;
the second mask strip comprises a third sub-mask strip and a fourth sub-mask strip spliced with each other; the fourth sub-mask strip comprises a second hollow region; and a thickness of a central region of the third sub-mask strip is less than a thickness of an edge region of the third sub-mask strip, the edge region of the third sub-mask strip surrounding the central region of the third sub-mask strip;
in a case where orientations of the first mask plate and the second mask plate are the same, a relative position relation of the spliced first and second sub-mask strips is the same as a relative position relation of the spliced third and fourth sub-mask strips; and
performing evaporation on the second portion of the to-be-evaporated region comprises:
moving the evaporation object;
aligning the evaporation object with the second mask plate such that the second hollow region of the second mask plate aligns with the second portion of the to-be-evaporated region; and
performing evaporation on the second portion of the to-be-evaporated region by using the second mask plate.

16. The method of claim 13, wherein the first mask plate comprises a first shielding strip arranged side by side with the first mask strip, and the first shielding strip is provided with an alignment mark, and
aligning the evaporation object with the first mask plate comprises aligning the evaporation object with the first mask plate by using the alignment mark on the first shielding strip.

17. The method of claim 15, wherein the second mask plate comprises a second shielding strip arranged side by side with the second mask strip, and the second shielding strip is provided with an alignment mark, and
aligning the evaporation object with the second mask plate comprises aligning the evaporation object with the second mask plate by using the alignment mark on the second shielding strip.
